(19) United States
(12) Patent Application Publication
(10) Pub. No.: US 2011/0254710 A1
(43) Pub. Date: Oct. 20, 2011

(54) PORTABLE ELECTRONIC DEVICE

(75) Inventors: Isamu Nakade, Ishikawa (JP); Akinori Oohira, Kanagawa (JP); Jun Takahashi, Miyagi (JP)

(73) Assignee: PANASONIC CORPORATION, Osaka (JP)

(21) Appl. No.: 13/141,954

(22) PCT Filed: Jun. 16, 2009
(86) PCT No.: PCT/JP2009/002746

§ 371 Date: Jun. 23, 2011

(30) Foreign Application Priority Data
Dec. 26, 2008 (JP) 2008-334627

(51) Int. Cl. H03K 17/94

(52) U.S. Cl. 341/35

(57) ABSTRACT

A portable electronic device in which a rotary key reliably operates is provided. The portable electronic device includes: a circuit board; a first cover disposed above the circuit board; a second cover disposed above the first cover; a gap disposed between the first cover and the second cover; holes provided in the first cover and the second cover; and a rotary key fixed to the circuit board and provided in the holes.

### TECHNICAL FIELD

The present invention relates to a portable electronic device including a rotary key.

### BACKGROUND ART

A related-art portable sliding electronic device includes a rotary key provided on an upper housing movable along a connection portion provided on a lower housing, so as to allow that a user to operate the portable electronic device (for example, Patent Document 1).

FIG. 5 shows a front view of a related-art portable sliding electronic device 800 (hereinafter referred to as a “portable electronic device 800”). As shown FIG. 5, the portable electronic device 800 includes: a lower housing 801; and an upper housing 802 configured to slide relative to the lower housing 801 via a connection portion (not shown) provided on the lower housing 801.

A user of the portable electronic device 800 can select functions of the portable electronic device 800 displayed on a liquid crystal display portion 804 by rotating a rotary key 805 (along an arrow A show in FIG. 5) provided on the upper housing 802. When the user of the portable electronic device 800 presses a switch 803 provided on a side surface of the lower housing 801, the upper housing 802 slides relative to the lower housing 801.

With reference to FIG. 6, a configuration of the upper housing 802 is described. FIG. 6 is a cross sectional view taken along a line VI-VI shown in FIG. 5. In FIG. 6 an X-axis (a substantially vertical direction) is illustrated so as correspond to a height of the sheet. As shown in FIG. 6, the upper housing 802 includes: a lower cover 808; a circuit board 807 fixed to an upper surface 808A of the lower cover 808 and including a key switch 807A provided on an upper surface 807B thereof; a key sheet 813 fixed to the key switch 807A; the rotary key 805 fixed to an upper surface 813A of the key sheet 813; and an upper cover 806. The circuit board 807 and the key sheet 803 are sandwiched between the upper cover 806 and the lower cover 808, thereby constituting the upper housing 802.

The rotary key 805 includes: a base plate portion 805A fixed to the upper surface 813A of the key sheet 813; a substantially cylindrical rotation portion 805B provided on an upper surface 805A′ of the base plate portion 805A and rotatable 360 degrees with respect to the base plate portion 805A in a substantially horizontal direction; and an enter key 805C. The rotation portion 805B is hollow. In the hollow space, the substantially cylindrical enter key 805C fixed to the upper surface 813A of the key sheet 813 is provided. The rotation portion 805B and the enter key 8050 extend up to the upper cover 806. An upper surface of the rotation portion 805B and an upper surface of the enter key 805C are exposed through a hole 806A provided in the upper cover 806.

The user of the portable electronic device 800 can rotate the rotation portion 805B of the rotary key 805 360 degrees in the substantially horizontal direction while pressing the upper surface 805B′ of the rotation portion 805B. Press force provided by the rotation operation is transmitted to the key switch 807A on the circuit board 807 through the base plate portion 805A and key sheet 813 and converted into an electric signal by an electronic component (e.g., a pressure sensor) provided on the circuit board 807. The user of the portable electronic device 800 can select functions of the portable electronic device 800 displayed on the liquid crystal display portion 804 by the rotation operation of the rotary key 805. Further, the user of the portable electronic device 800 can determine the function selected from the various functions of the portable electronic device 800 by the rotary key 805, by pressing the upper surface of the enter key 8050, thereby operating the portable electronic device 800 to execute the determined function.

As shown in FIG. 6, between the rotation portion 805B and the upper cover 806, a gap for rotating the rotation portion 805B of the rotary key 805 is present over an entire peripheral surface of the rotation portion 805B. The gap refers to a gap between the rotary key 805 and the upper cover 806 formed when the rotary key 805 is placed in the hole 806A. When the user of the portable electronic device 800 spills viscous liquid (hereinafter described as “liquid”) on the upper surface of the rotation portion 805B, the liquid enters into the upper housing 802 from the gap between the peripheral surface of the rotation portion 805B and a side surface of the upper cover 806. The liquid entering into the upper housing 802 flows into a gap A between the upper cover 806 and the key sheet 813 as indicated by an arrow A shown in FIG. 6.

### RELATED ART DOCUMENTS

### Patent Documents

Patent Document 1: JP-A-2001-292213

### SUMMARY OF THE INVENTION

Problem to be Solved by the Invention

However, a part of the viscous liquid stays and is solidified in the vicinity of the rotary key 805 in the upper housing 802. The term “in the vicinity of the rotary key 805” means a boundary area between the base plate portion 805A and the rotation portion 805B, a part or entirety of peripheral surface of the rotation portion 805B, etc. When the viscous liquid stays around the rotary key 805 and is solidified thereby coupling the upper cover 806 or the key sheet 813 with the rotary key 805, the rotation portion 805B of the rotary key 805 can not rotate, so that the rotary key 805 does not work. Further, when the viscous liquid reaches the circuit board 807 below the key sheet 813, a short circuit may occur in a path that electrically interconnects electronic components of the circuit board 807. For this reason, the user of the portable electronic device 800 becomes unable to select the various functions of the portable electronic device 800 by rotating the rotary key 805.

An object of the present invention is to provide a portable electronic device in which a rotary key reliably operates.

### Means for Solving the Problem

The present invention provides a portable electronic device including: a circuit board; a first cover disposed above the circuit board; a second cover disposed above the first cover; a gap disposed between the first cover and the second cover; holes provided in the first cover and the second cover; and a rotary key fixed to the circuit board and provided in the holes.

In the portable electronic device, the circuit board further includes a liquid crystal display portion, and a part of the liquid crystal display portion is covered with the first cover.

In the portable electronic device, a water absorbing member is provided in a part or entirety of the gap.

In the portable electronic device, a distance between the second cover and the rotary key is smaller than a distance between the first cover and the rotary key.

### Advantages of the Invention

In the portable electronic device of the present invention, the rotary key reliably operates.

### BRIEF DESCRIPTION OF THE DRAWINGS

FIG. 1 is a front view of a portable electronic device 100 of an embodiment of the present invention.

FIG. 2 is an exploded perspective view of an upper housing 102.

FIG. 3 is a partially enlarged view of an upper surface of the upper housing 102.

FIG. 4 is a cross-sectional view taken along a line IV-IV shown in FIG. 3.

FIG. 5 is a front view of a related-art portable sliding electronic device 800.

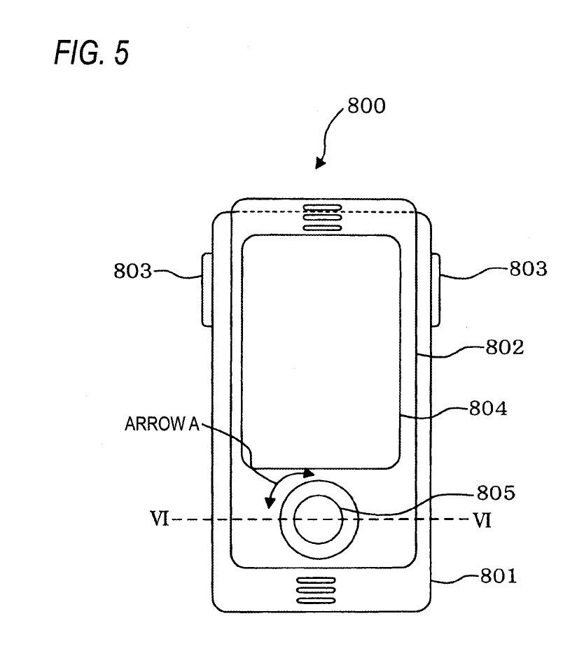

FIG. 6 is a cross-sectional view taken along a line VI-VI shown in FIG. 5.

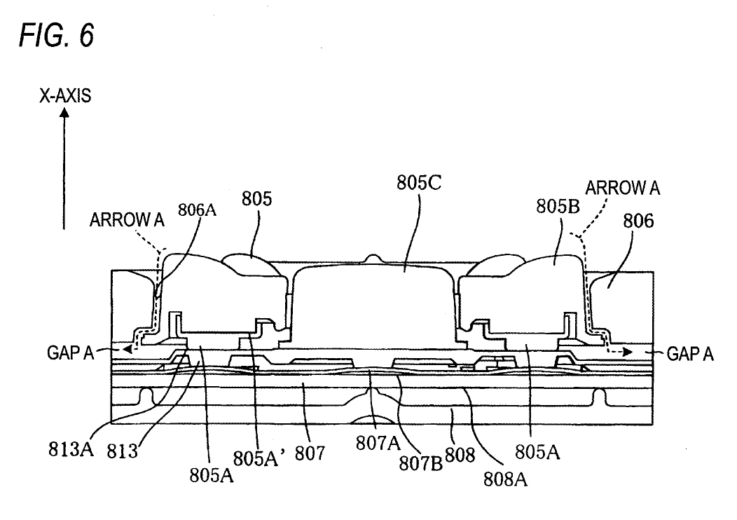

### MODE FOR CARRYING OUT THE INVENTION

An embodiment of the present invention is described by reference to the drawings.

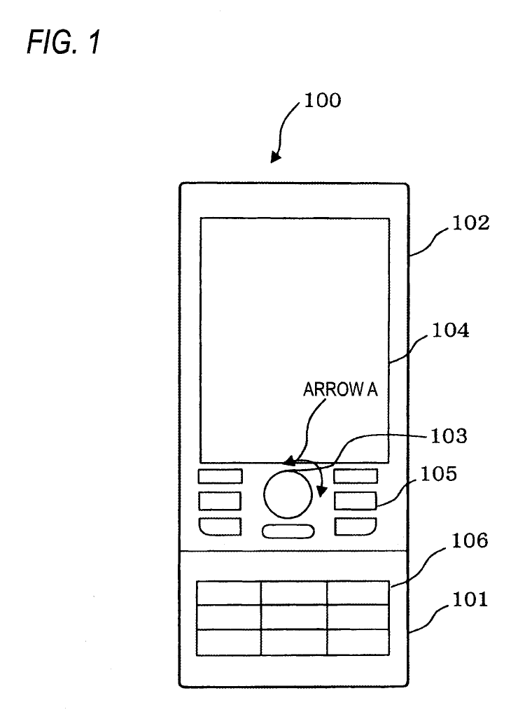

FIG. 1 is a front view of a portable electronic device 100 of an embodiment of the present invention. As shown in FIG. 1, the portable electronic device 100 includes: a lower housing 101; and an upper housing 102 configured to slide relative to the lower housing 101 via a connection portion (not shown) provided on the lower housing 101.

A user of the portable electronic device 100 can select various functions of a portable electronic device 800 displayed on a liquid crystal display portion 104 by rotation operation of a rotary key 103 (serving as a rotary key in the present invention) provided on the upper housing 102. Further, the user of the portable electronic device 100 can also select the various functions of the portable electronic device 100 by pressing a plurality of buttons 105 provided around the rotary key 103 and buttons 106 of the lower housing 101, instead of operating the rotary key 103.

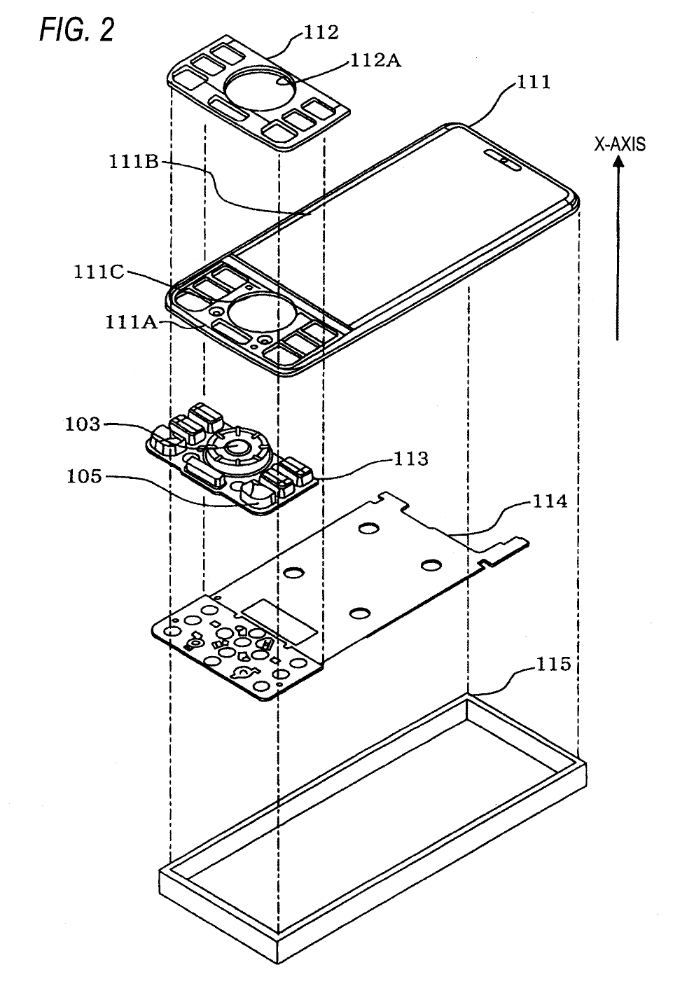

A configuration of the upper housing 102 is now described with reference to FIG. 2. FIG. 2 is an exploded perspective view of the upper housing 102. In FIG. 2, an X-axis (a substantially vertical direction) is illustrated so as to correspond to a height of the sheet. As shown in FIG. 2, the upper housing 102 includes: a first cover 111 (serving as a first cover of the present invention); a second cover 112 (serving as a second cover of the present invention); a key sheet 113; a circuit board 114; and a lower cover 115. In the upper housing 102, the key sheet 113 and the circuit board 114 are sandwiched between the first cover 111 and the lower cover 115.

The circuit board 114 is fixed to an upper surface 115A of the lower cover 115. On an upper surface of the circuit board 114, a key switch 114A and electronic components for implementing various functions of the portable electronic device are mounted. Further, the upper surface of the circuit board 114 has an area used for fixing the key sheet 113 and another area used for fixing a liquid crystal element (not shown).

The key sheet 113 includes: a substantially circular rotary key 103 (hereinafter described as a “rotary key 103”); and a plurality of buttons 105. The key sheet 113 is fixed to the circuit board 114 via the key switch 114A. When the upper housing 102 is assembled, the rotary key 103 and the plurality of buttons 105 extend up to the second cover 112 from holes formed in the first cover 111 and the second cover 112. A user of the portable electronic device 100 can operate the rotary key 103 and the plurality of buttons 105 from the upper surface of the second cover 112.

The first cover 111 includes a first portion 111A and a protective cover 111B. The first portion 111A includes a plurality of holes used for fitting the rotary key 103 and the plurality of buttons 105 of the key sheet 113. The rotary key 103 extends from a hole 111C (serving as a hole formed in the first cover of the present invention) shown in FIG. 2 among the plurality of holes. The holes are formed by boring the first portion 111A so as to substantially correspond to a shape of the rotary key 103 to be fitted and shapes of the plurality of buttons 105 to be fitted. The protective cover 111B protects the liquid crystal element fixed to the circuit board 114. The protective cover 111B is a part of the first cover 111. The first cover 111 also has a function of preventing upward removal of the rotary key 103 (in a direction of the X-axis in FIG. 2 (the substantially vertical direction), and the same also applies to corresponding expressions provided hereunder).

The second cover 112 is disposed above the first cover 111 and covers the first portion 111A of the first cover 111 through the second gap. The second cover 112 includes a plurality of holes used for fitting the rotary key 103 and the plurality of buttons 105 of the key sheet 113, similar to the first cover 111. The rotary key 103 extends from a hole 112A (serving as a hole provided in the second cover of the present invention) shown in FIG. 2 among the plurality of holes. The holes are formed by boring a part of the second cover 112 so as to substantially correspond to the shape of the rotary key 103 and the shapes of the plurality of buttons 105.

The lower cover 115 fixes the circuit board 114. The circuit board 114 is sandwiched between the lower cover and the first cover 111, thereby constituting the upper housing 102.

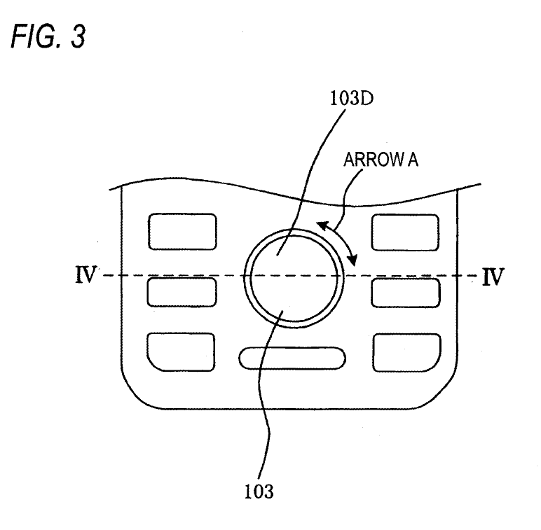

FIG. 3 is a partially enlarged view of the upper surface of the upper housing 102.

As shown in FIG. 3, a portion of the rotary key 103 exposed from the second cover 112 is an upper surface 103D of the rotary key 103 and has a circular shape. A gap for rotation operation of the rotary key 103 is provided between the upper surface 103D of the rotary key 103 and the second cover 112.

The user of the portable electronic device 100 can rotate the rotary key 103 360 degrees in the substantially horizontal direction (a direction of an arrow A in FIG. 3) while pressing the upper surface of the rotary key 103.

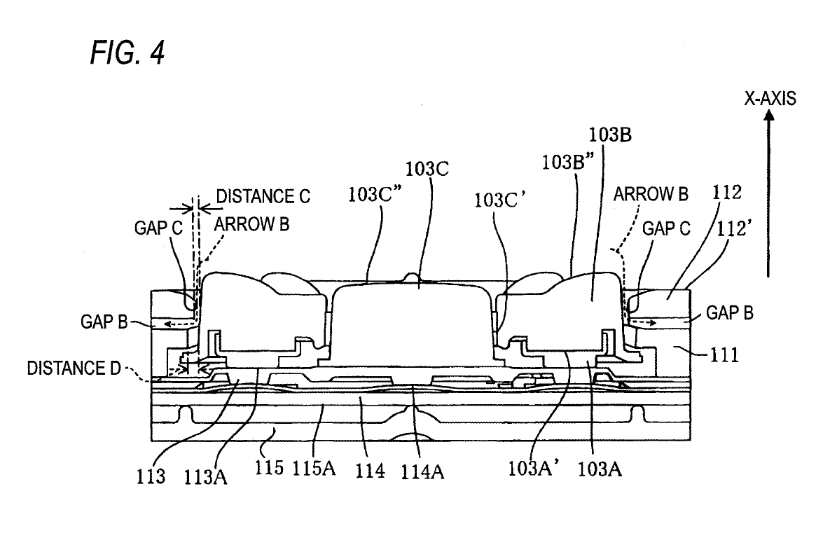

A surrounding area of the rotary key 103 is shown in cross section of the upper housing 102. FIG. 4 is a cross-sectional view taken along a line IV-IV shown in FIG. 3. In FIG. 4, the X-axis (a substantially vertical direction) is illustrated so as to correspond to a height of the sheet.

As shown in FIG. 4, the rotary key 103 includes a base plate portion 103A, a rotation portion 103B, and an enter key 103C. The enter key 103C is substantially cylindrical and disposed at the center of the rotary key 103. The enter key 103C is fixed to the key sheet 113.

The base plate portion 103A is fixed to an upper surface 113A of the key sheet 113. The base plate portion 103A is substantially cylindrical, and a center part of the base plate portion 103A is hollow. The enter key 103C is disposed in the hollow gap. The base plate portion 103A surrounds a peripheral surface of the enter key 103C. The rotation portion 103B is fixed to an upper surface 103A′ of the base plate portion 103A. Similar to the base plate portion 103A, the rotation portion 103B has a substantially cylindrical shape, and a center part of the rotation portion is hollow. The substantially cylindrical enter key 103C is disposed in the hollow gap. The enter key 103C is fixed to the upper surface 113A of the key sheet 113. The rotation portion 103B surrounds a peripheral surface 103C′ of the enter key 103C.

The user of the portable electronic device 100 can rotate the rotation portion 103B 360 degrees in a substantially horizontal direction while pressing an upper surface 103B″ of the rotation portion 103B. Press force provided by the rotation operation is transmitted to the circuit board 114 via the base plate portion 103A and the key sheet 113 and is converted into an electric signal by the electronic device (e.g., a pressure sensor) provided on the circuit board 114. It is possible to select the various functions of the portable electronic device 100 displayed on the liquid crystal element by the rotation operation of the rotation portion 103B.

The user of the portable electronic device 100 can determine the function of the portable electronic device 100 selected by the rotation portion 103B by pressing an upper surface 103C of the enter key 103, thereby operating the portable electronic device 100 to execute the determined function.

As shown in FIG. 4, the rotation portion 103B extends in a substantially vertical direction up to an upper surface 112′ of the second cover 112 through the holes 111C and 112A provided in the first cover 111 and the second cover 112. An upper surface of the rotation portion 103B is exposed outside from the hole 112A provided in the second cover 112. A gap for rotation of the rotation portion 103B is present between the rotation portion 103B and the second cover 112.

As indicated by an arrow B shown in FIG. 4, when the user of the portable electronic device 100 spills, for example, viscous liquid (hereinafter referred to as “liquid”) on the upper surface of the rotation portion 103B, the liquid enters into the upper housing 102 from a gap C between the rotation portion 103B and the second cover 112.

In the portable electronic device 100 of the first embodiment of the present invention, a gap B (serving as a gap disposed between the first cover and the second cover in the present invention) is present between the first cover 111 and the second cover 112 disposed above the first cover 111. Therefore, the large part of liquid entering into the upper housing 102 from the gap between the rotation portion 103B and the second cover 112 flows into the gap B between the second cover 112 and the first cover 111. Therefore, the liquid does not stay in the vicinity of the rotary key 103, so that the rotary key 103 operates without fail.

The term “in the vicinity of the rotary key 103” means a boundary area between the base plate portion 103A and the rotation portion 103B, a part or entirety of the peripheral surface of the rotation portion 103B, etc. In other words, the term “in the vicinity of the rotary key 103” corresponds to a portion of the configuration of the upper housing 102 in which the rotary key 103 does not rotate if the liquid is solidified.

Since an amount of liquid which does not flow into the gap B between the second cover 112 and the first cover 111 is very small, and the rotary key 103 is avoided from not working. Moreover, since the amount of liquid which does not flow into the gap B between the second cover 112 and the first cover 11 is very small, the liquid may not reach the circuit board 114 below the key sheet 113 and may not cause a short circuit in a path that electrically interconnects the electronic components of the circuit board 114.

As shown in FIG. 4, in substantially horizontal direction, a distance C between the second cover 112 and the rotary key 113 is smaller than a distance D between the first cover 111 and the rotary key 113. The first cover 111 is made invisible from the above by the configuration. As a result, a design feature of the portable electronic device is enhanced, and the liquid dropped from the above can actively be guided to the gap B.

As described above, in the portable electronic device of the embodiment of the present invention, even if a liquid enters into the portable electronic device, the viscous liquid will not stay in the vicinity of the rotary key. Moreover, in the portable electronic device of the embodiment of the present invention, since the liquid does not reach the circuit board, a short circuit does not occur in the electrical paths of the circuit board. Therefore, the portable electronic device of the embodiment of the present invention enables reliable operation of the rotary key.

The shape of the portable electronic device of the embodiment of the present invention is not particularly limited. The present invention may be applied to a portable electronic device of any shape, so long as the portable electronic device includes a rotary key.

In the portable electronic device of the embodiment of the present invention, the shape of the rotary key 103 is described to be circular, but the shape is not limited to the circular shape. Instead of the circular shape, the shape of the rotary key 103 may be an elliptical shape, a polygonal shape, or a regular polygon, so long as the shape enables performance of rotation operation.

Moreover, a water absorbing member, such as a water absorbing gel or a water absorbing sheet, may be provided in a part or entirety of the gap B. With this configuration, it is possible to actively eliminate liquid flowing into the gap B.

Although the present invention has been described in detail with reference to the specific embodiment, it is apparent to those skilled in the art that various changes or modifications may be made without departing from the spirit and scope of the invention.

The present patent application is based on Japanese Patent Application (Application No. 2008-334627) filed on Dec. 26, 2008, the entire contents of which are incorporated herein by reference.

### INDUSTRIAL APPLICABILITY

The portable electronic device of the present invention provides an advantage of reliable operation of the rotary key and is useful for a portable phone, etc.

### DESCRIPTION OF REFERENCE SIGNS

100, 800 PORTABLE ELECTRONIC DEVICE

101, 801 LOWER HOUSING

102, 802 UPPER HOUSING

103, 805 ROTARY KEY

103A, 805A BASE PLATE PORTION

103B, 805B ROTATION PORTION

103C, 805C ENTER KEY

104, 804 LIQUID CRYSTAL DISPLAY PORTION

105 PLURALITY OF BUTTONS

106 BUTTON

111 FIRST COVER

111A FIRST PORTION

111B PROTECTIVE COVER

111C HOLE

112 SECOND COVER

112A HOLE

113 KEY SHEET

114, 807 CIRCUIT BOARD

115, 808 LOWER COVER

803 SWITCH

806 UPPER COVER

1. A portable electronic device comprising:
a circuit board;
a liquid crystal display portion provided on the circuit board;
a first cover disposed above the circuit board;
a second cover disposed above the first cover;
a gap disposed between the first cover and the second cover;
holes provided in the first cover and the second cover; and
a rotary key fixed to the circuit board and provided in the holes
wherein the first cover comprises:
a first portion on which the second cover is provided; and
a second portion configured to protect the liquid display portion, and
wherein a distance between a surface of the second cover opposing the rotary key and a side surface of the rotary key is smaller than a distance between a surface of the first cover opposing the rotary key and the side surface of the rotary key.

2. (canceled)

3. The portable electronic device according to claim 1,
wherein a water absorbing member is provided in a part of the gap.

4. (canceled)
